(19) United States
(12) Patent Application Publication
(10) Pub. No.: US 2024/0422982 A1
(43) Pub. Date: Dec. 19, 2024

(54) SEMICONDUCTOR DEVICE AND MANUFACTURING METHOD THEREOF

(71) Applicant: Kioxia Corporation, Tokyo (JP)

(72) Inventors: Daisuke KITAGAWA, Yokkaichi Mie (JP); Kensei TAKAHASHI, Kuwana Mie (JP)

(73) Assignee: Kioxia Corporation, Tokyo (JP)

(21) Appl. No.: 18/740,858

(22) Filed: Jun. 12, 2024

(30) Foreign Application Priority Data
Jun. 15, 2023 (JP) 2023-098769

(51) Int. Cl. H10B 43/30; H10B 43/27

(52) U.S. Cl. CPC H10B 43/30; H10B 43/27

(57) ABSTRACT

A semiconductor device according to the present embodiment includes a first insulator, a conductive layer, and a film. The film is provided between the first insulator and the conductive layer and contains carbon (C) or silicon (Si). The semiconductor device further comprises a stacked body in which insulating layers and the conductive layers are alternately stacked in a first direction, a semiconductor layer disposed in the first direction in the stacked body, a second insulator disposed in the first direction between the stacked body and the semiconductor layer, a third insulator disposed in the first direction between the stacked body and the second insulator, and a fourth insulator disposed in the first direction between the stacked body and the third insulator. The first insulator is disposed between the conductive layers and the insulating layers and between the conductive layers and the fourth insulator.

### CROSS REFERENCE TO RELATED APPLICATIONS

This application is based upon and claims the benefit of priority from the prior Japanese Patent Application No. 2023-098769, filed on Jun. 15, 2023, the entire contents of which are incorporated herein by reference.

### FIELD

The embodiments of the present invention relate to a semiconductor device and a manufacturing method thereof.

### BACKGROUND

ANAND flash memory in which memory cells are three-dimensionally disposed is known as a semiconductor device. Impurity diffusion at a manufacturing stage and the like potentially leads to electric property degradation.

### BRIEF DESCRIPTION OF THE DRAWINGS

FIG. 1 is a perspective view illustrating the structure of a semiconductor device of a first embodiment;

FIG. 2 is a cross sectional view illustrating a method of manufacturing the semiconductor device of the first embodiment;

FIG. 3 is a cross sectional view illustrating the method of manufacturing the semiconductor device of the first embodiment;

FIG. 4 is a cross sectional view illustrating the method of manufacturing the semiconductor device of the first embodiment;

FIG. 5 is a cross sectional view illustrating the method of manufacturing the semiconductor device of the first embodiment;

FIG. 6 is a cross sectional view illustrating the method of manufacturing the semiconductor device of the first embodiment;

FIG. 7 is a cross sectional view illustrating the structure of the semiconductor device of the first embodiment;

FIG. 8A is a cross sectional view illustrating the method of manufacturing the semiconductor device of the first embodiment;

FIG. 8B is a cross sectional view illustrating the method of manufacturing the semiconductor device of the first embodiment;

FIG. 8C is a cross sectional view illustrating the method of manufacturing the semiconductor device of the first embodiment;

FIG. 8D is a cross sectional view illustrating the method of manufacturing the semiconductor device of the first embodiment;

FIG. 9 is a graph illustrating concentration distribution of carbon in the first embodiment;

FIG. 10 is a cross sectional view illustrating a method of manufacturing a semiconductor device of a first comparative example of the first embodiment;

FIG. 11A is a cross sectional view illustrating a method of manufacturing a semiconductor device of a second comparative example of the first embodiment;

FIG. 11B is a cross sectional view illustrating the method of manufacturing the semiconductor device of the second comparative example of the first embodiment;

FIG. 12 is a cross sectional view illustrating the structure of a semiconductor device of a second embodiment;

FIG. 13A is a cross sectional view illustrating a method of manufacturing the semiconductor device of the second embodiment;

FIG. 13B is a cross sectional view illustrating the method of manufacturing the semiconductor device of the second embodiment;

FIG. 13C is a cross sectional view illustrating the method of manufacturing the semiconductor device of the second embodiment;

FIG. 13D is a cross sectional view illustrating the method of manufacturing the semiconductor device of the second embodiment;

FIG. 14A is a cross sectional view illustrating a method of manufacturing a semiconductor device of a comparative example of the second embodiment;

FIG. 14B is a cross sectional view illustrating the method of manufacturing the semiconductor device of the comparative example of the second embodiment;

FIG. 14C is a cross sectional view illustrating the method of manufacturing the semiconductor device of the comparative example of the second embodiment;

FIG. 15 is a cross sectional view illustrating the structure of a semiconductor device of a third embodiment;

FIG. 16A is a cross sectional view illustrating a method of manufacturing the semiconductor device of the third embodiment;

FIG. 16B is a cross sectional view illustrating the method of manufacturing the semiconductor device of the third embodiment;

FIG. 17 is a cross sectional view illustrating the structure of a semiconductor device of a fourth embodiment;

FIG. 18 is a cross sectional view illustrating a method of manufacturing the semiconductor device of the fourth embodiment;

FIG. 19 is a cross sectional view illustrating the method of manufacturing the semiconductor device of the fourth embodiment; and

FIG. 20 is a cross sectional view illustrating the structure of a semiconductor device of a comparative example of the fourth embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a first insulator, a conductive layer, and a film. The film is provided between the first insulator and the conductive layer and contains carbon (C) or silicon (Si).

### First Embodiment

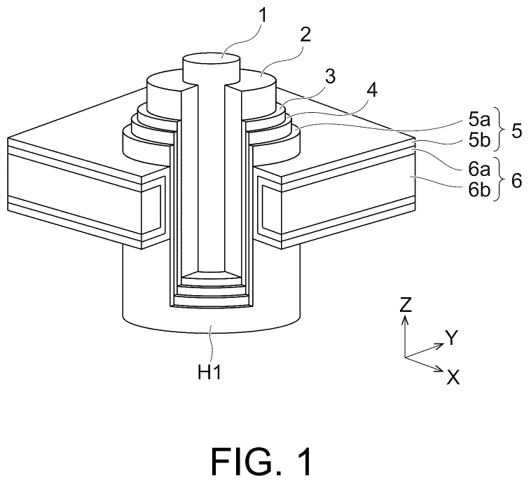

FIG. 1 is a perspective view illustrating the structure of a semiconductor device of a first embodiment. The semiconductor device in FIG. 1 is, for example, a three-dimensional NAND memory.

The semiconductor device in FIG. 1 includes a core insulator 1, a channel semiconductor layer 2, a tunnel insulator 3, an electric charge accumulation film 4, a block insulator 5, and an electrode layer 6. The block insulator 5 includes an insulator 5a and an insulator 5b. The electrode layer 6 includes a barrier metal layer 6a and an electrode material layer 6b. The insulator 5a is an example of a first insulator, the tunnel insulator 3 is an example of a second insulator, and the channel semiconductor layer 2 is an example of a first semiconductor layer. The tunnel insulator 3, the electric charge accumulation film 4, and the block insulator 5 are also referred to as a cell multilayer film.

In the semiconductor device of the present embodiment, a plurality of electrode layers and a plurality of insulating layers are alternately stacked on a substrate, and a memory hole H1 is provided in the electrode layers and the insulating layers. FIG. 1 illustrates the electrode layer 6 as one of the electrode layers. The electrode layers function as, for example, word lines of a NAND memory. FIG. 1 illustrates an X direction and a Y direction parallel to the surface of the substrate and orthogonal to each other, and a Z direction orthogonal to the surface of the substrate. In the present specification, the positive Z direction is treated as the upward direction and the negative Z direction is treated as the downward direction. The negative Z direction may be or may not be aligned with the direction of gravity.

The core insulator 1, the channel semiconductor layer 2, the tunnel insulator 3, the electric charge accumulation film 4, and the insulator 5a are formed in the memory hole H1 and constitute a memory cell of a NAND memory. The insulator 5a is formed on the surfaces of the electrode layers and the insulating layers in the memory hole H1, and the electric charge accumulation film 4 is formed on the surface of the insulator 5a. The electric charge accumulation film 4 can accumulate electric charge between an outer side surface and an inner side surface. The tunnel insulator 3 is formed on the surface of the electric charge accumulation film 4, and the channel semiconductor layer 2 is formed on the surface of the tunnel insulator 3. The channel semiconductor layer 2 functions as a channel of the memory cell. The core insulator 1 is formed in the channel semiconductor layer 2.

The insulator 5a is, for example, a SiO film (silicon oxide film). The electric charge accumulation film 4 is, for example, a SiN film (silicon nitride film). The tunnel insulator 3 is, for example, a SiON film (silicon oxynitride film). The channel semiconductor layer 2 is, for example, a polysilicon layer. The core insulator 1 is, for example, a silicon oxide film.

The insulator 5b, the barrier metal layer 6a, and the electrode material layer 6b are formed between insulating layers adjacent to each other and sequentially formed on the lower surface of the upper insulating layer, the upper surface of the lower insulating layer, and the side surface of the insulator 5a. The insulator 5b is, for example, a metal insulator made of aluminum oxide or the like. The barrier metal layer 6a is, for example, a titanium nitride film. The electrode material layer 6b is, for example, a W (tungsten) layer.

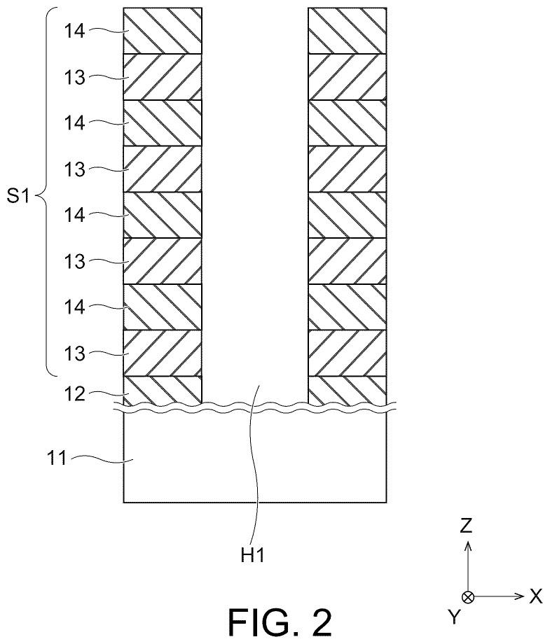

FIGS. 2 to 6 are cross sectional views illustrating a method of manufacturing the semiconductor device of the first embodiment.

First, an insulator 12 is formed above a substrate 11, and a plurality of sacrifice layers 13 and a plurality of insulating layers 14 are alternately formed on the insulator 12 (FIG. 2). As a result, a multilayer film S1 alternately including the plurality of sacrifice layers 13 and the plurality of insulating layers 14 is formed on the insulator 12. The substrate 11 is, for example, a semiconductor substrate such as a silicon substrate. The insulator 12 is, for example, a silicon oxide film (SiO). Each sacrifice layer 13 is, for example, a silicon nitride film (SiN), and each insulating layer 14 is, for example, a silicon oxide film (SiO).

Subsequently, the memory hole H1 penetrating through the multilayer film S1 and the insulator 12 is formed (FIG. 2). As a result, the upper surface of a layer provided between the substrate 11 and the insulator 12 is exposed in the memory hole H1. Details of the layer will be described later.

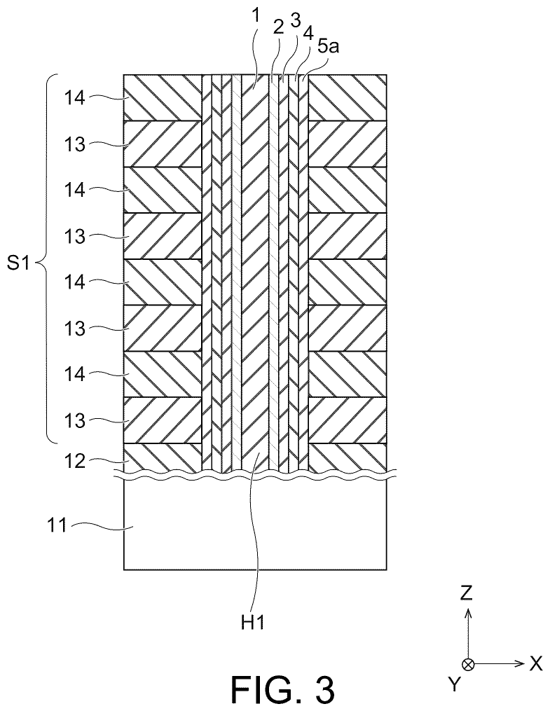

Subsequently, the insulator 5a, the electric charge accumulation film 4, the tunnel insulator 3, and part of the channel semiconductor layer 2 are sequentially formed in the memory hole H1 (FIG. 3). Subsequently, the insulator 5a, the electric charge accumulation film 4, the tunnel insulator 3, and the part of the channel semiconductor layer 2 are removed from a bottom part of the memory hole H1 by etching, and then, the rest of the channel semiconductor layer 2 and the core insulator 1 are sequentially formed in the memory hole H1 (FIG. 3). As a result, the insulator 5a, the electric charge accumulation film 4, the tunnel insulator 3, the channel semiconductor layer 2, and the core insulator 1 are sequentially formed on the side surfaces of the multilayer film S1 and the insulator 12 in the memory hole H1.

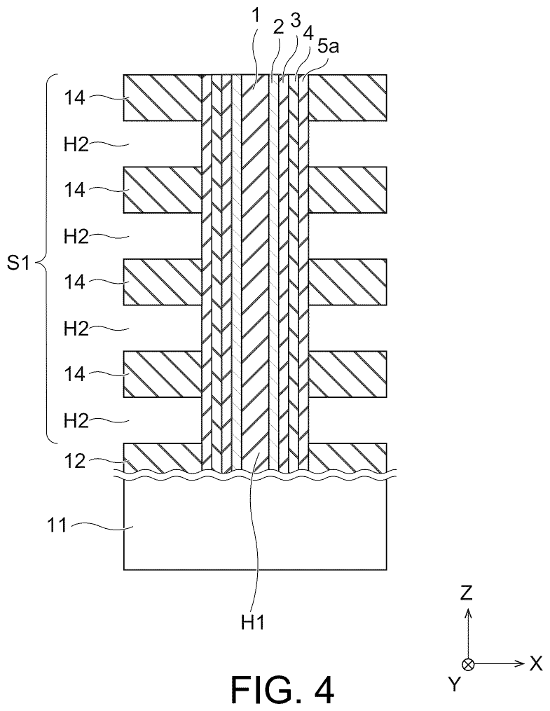

Subsequently, a slit (not illustrated) is formed in the multilayer film S1 and used to remove the sacrifice layers 13 with liquid chemical such as phosphoric acid. As a result, a plurality of hollow spaces H2 are formed between the insulating layers 14 (FIG. 4).

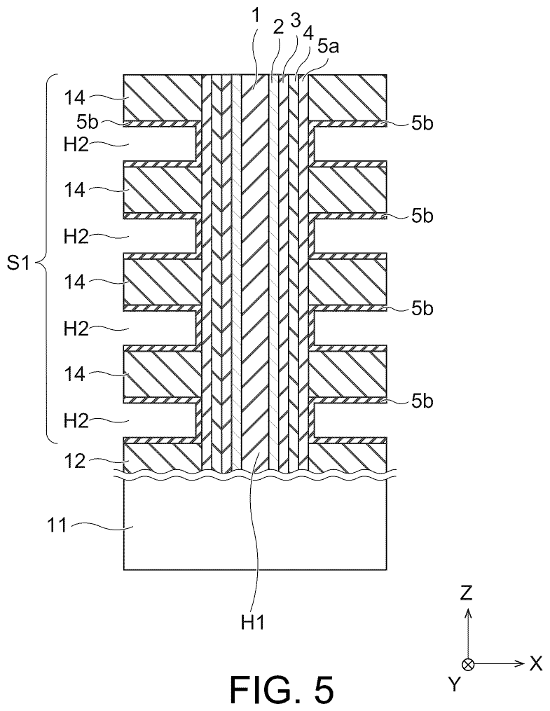

Subsequently, the insulator 5b containing aluminum oxide is formed on the surfaces of the insulating layers 14 and the insulator 5a in the hollow spaces H2 (FIG. 5). As a result, the block insulator 5 including the insulator 5a and the insulator 5b is formed.

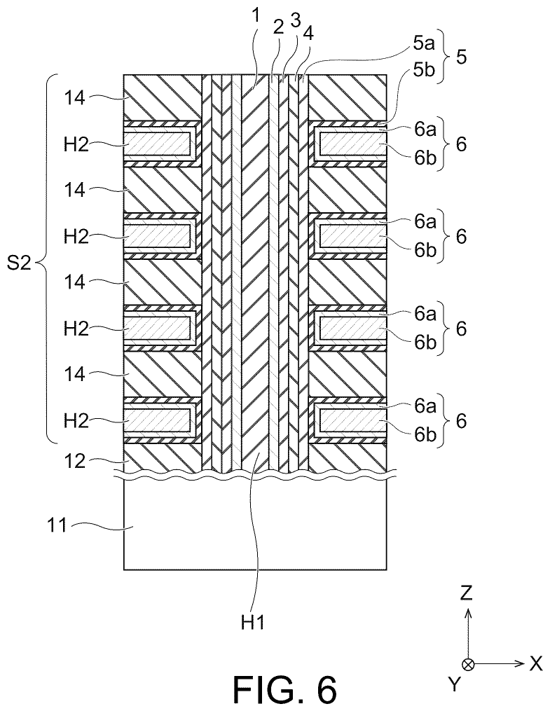

Subsequently, the barrier metal layer 6a and the electrode material layer 6b are sequentially formed on the surface of the insulator 5b in the hollow spaces H2 (FIG. 6). As a result, the electrode layer 6 including the barrier metal layer 6a and the electrode material layer 6b is formed in each hollow space H2, and a multilayer film S2 alternately including the plurality of electrode layers 6 and the plurality of insulating layers 14 is formed on the insulator 12. Treatment that removes the sacrifice layers 13 and forms the insulator 5b, the barrier metal layer 6a, and the electrode material layer 6b is referred to as replacement treatment.

In this manner, the semiconductor device of the present embodiment is manufactured (FIG. 6). FIG. 1 illustrates part of the semiconductor device illustrated in FIG. 6.

The interface between the insulator 5b and each electrode layer 6 will be described below in detail.

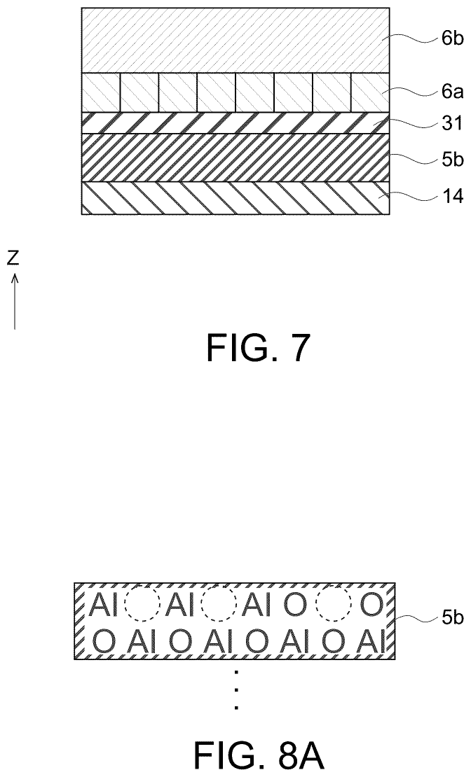

FIG. 7 is a cross sectional view illustrating the structure of the semiconductor device of the first embodiment. FIG. 7 is also an enlarged cross sectional view of the interface between the insulator 5b and each electrode layer 6.

The semiconductor device further includes a film 31. The film 31 is provided between the insulator 5b and the barrier metal layer 6a (electrode material layer 6b). The film 31 is, for example, a layer containing carbon (C). As described later, continuity of the barrier metal layer 6a can be improved by providing the film 31. Moreover, damage on the insulator 5b by diffusion of fluorine (F) attributable to the precursor of the electrode material layer 6b can be reduced. Accordingly, electric property degradation can be reduced.

Note that, in the example illustrated in FIG. 7, the barrier metal layer 6a is provided between the film 31 and the electrode material layer 6b.

A method of manufacturing the film 31 and its surrounding components will be described below.

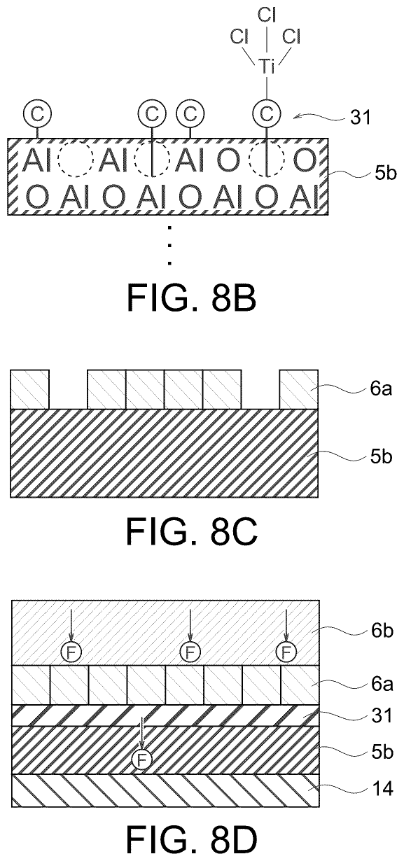

FIGS. 8A to 8D are cross sectional views illustrating the method of manufacturing the semiconductor device of the first embodiment.

First, as illustrated in FIG. 8A, the insulator 5b (Al₂O₃) is formed (refer to FIG. 5). There are losses at the outermost surface of the insulator 5b in some cases. In the example illustrated in FIG. 8A, some Al and O are lost.

Subsequently, as illustrated in FIG. 8B, the film 31 is formed on the insulator 5b, and initial core adsorption of titanium (Ti) is performed. The film 31 is formed by, for example, supplying C-series gas (and NH₃ or the like). TiCl₄ is used for initial core adsorption of Ti. C is likely to adsorb to Al₂O₃ in the insulator 5b, and TiCl₄ is likely to adsorb to C in the film 31. Initial core adsorption of Ti can be further improved with the film 31. Note that the precursor of the barrier metal layer 6a, such as TiCl₄ does not need to contain C.

Subsequently, as illustrated in FIG. 8C, the barrier metal layer 6a is formed. The barrier metal layer 6a contains, for example, titanium nitride (TiN). The barrier metal layer 6a is formed by, for example, nitriding adsorbed Ti. The barrier metal layer 6a is an extremely thin film, and thus initial core adsorption of Ti to the insulator 5b is insufficient and a discontinuous state (state with holes) potentially occurs at its part. However, continuity of the barrier metal layer 6a can be improved by forming the film 31 before initial core adsorption of Ti. Note that illustration of the film 31 is omitted in the example illustrated in FIG. 8C.

Subsequently, as illustrated in FIG. 8D, the electrode material layer 6b is formed on the barrier metal layer 6a. The electrode material layer 6b is formed by, for example, LP-CVD (low pressure chemical vapor deposition). The electrode material layer 6b is formed by, for example, repeatedly performing supply of tungsten hexafluoride (WF₆) gas and supply of diborane (B₂H₆) gas.

If F attributable to the precursor of the electrode material layer 6b diffuses to the insulator 5b and the insulating layer 14, electric properties are affected, which potentially leads to device performance degradation.

However, as illustrated in FIG. 8D, with the film 31, continuity of the barrier metal layer 6a can be improved and F diffusion can be reduced. Accordingly, damage on the insulator 5b due to F diffusion can be reduced. As a result, electric property degradation can be reduced.

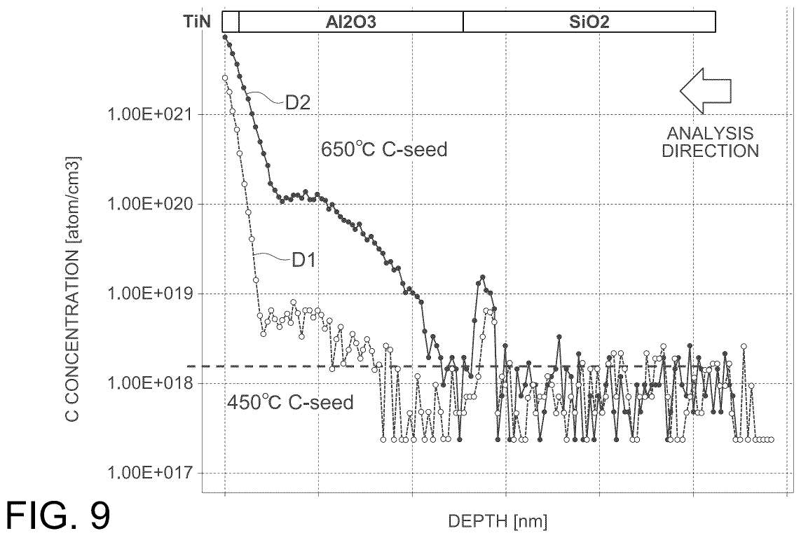

FIG. 9 is a graph illustrating concentration distribution of carbon (C) in the first embodiment. FIG. 9 is an analysis result by SIMS (secondary ion mass spectrometry). FIG. 9 illustrates an example in which treatment temperatures of 450° C. (data D1) and 650° C. (data D2) were used as deposition conditions of the film 31. The horizontal axis represents depth in the Z direction. The vertical axis represents C concentration. Note that the insulating layer 14 (SiO2) illustrated in FIG. 9 may be the substrate 11.

Note that the film 31 corresponds to a region at the interface between the insulator 5b and the barrier metal layer 6a.

The C concentration of the data D2 is higher than the C concentration of the data D1. This is because, when formation of the film 31 is performed at a higher temperature, C is more likely to adsorb to the insulator 5b and the C concentration becomes higher.

The interface between the insulator 5b and the barrier metal layer 6a has high C concentration. However, the insulating layer 14 has low C concentration equivalent to or lower than values with dashed lines illustrated in FIG. 9. Note that, as C diffuses to the insulator 5b, the insulator 5b obtains C concentration higher than the C concentration of the insulating layer 14. The concentration of C at the interface between the insulator 5b and the barrier metal layer 6a or the concentration of C between the insulator 5b and the electrode material layer 6b is, for example, equal to or higher than 1×10¹⁸ atom/cm³ as a detection lower limit value, but is preferably equal to or higher than a predetermined value. The predetermined value is, for example, 1×10¹⁹ atom/cm³.

As described above, according to the first embodiment, the film 31 is provided between the insulator 5b and the barrier metal layer 6a and contains carbon. Accordingly, continuity of the barrier metal layer 6a can be improved. As a result, diffusion of F attributable to the precursor of the electrode material layer 6b can be reduced. Damage on the insulator 5b due to F diffusion can be reduced, and electric property degradation can be reduced.

Note that the film 31 may contain silicon (Si) in place of C.

Detection of carbon concentration is not limited to SIMS but may use section TEM (transmission electron microscope)-EDS (energy dispersive x-ray spectroscopy) mapping.

Moreover, when carbon concentration is high, the film 31 can be detected by XPS (X-ray photoelectron spectroscopy) as well.

In the above description of the first embodiment, F attributable to the precursor of the electrode material layer 6b diffuses in a direction (the Z direction) toward the insulating layer 14. However, F attributable to the precursor of the electrode material layer 6b potentially diffuses in a direction (the X direction and the Y direction) toward the insulator 5a. Diffusion of F to the insulator 5a potentially leads to electric property degradation such as erase saturation degradation.

Furthermore, the problem with F diffusion is more significant as the film thickness of the barrier metal layer 6a is smaller. However, the configuration illustrated in FIG. 7 is applicable irrespective of the film thickness of the barrier metal layer 6a. For example, the configuration illustrated in FIG. 7 is not limited to the memory pillar structure illustrated in FIG. 1 but is also applicable to a structure in which an insulator, a barrier metal layer, and an electrode material layer are stacked, for example, a wire or the like used in a semiconductor device. In this case, the wire is disposed at an insulator corresponding to the insulator 5b and includes an electrode material layer corresponding to the electrode material layer 6b.

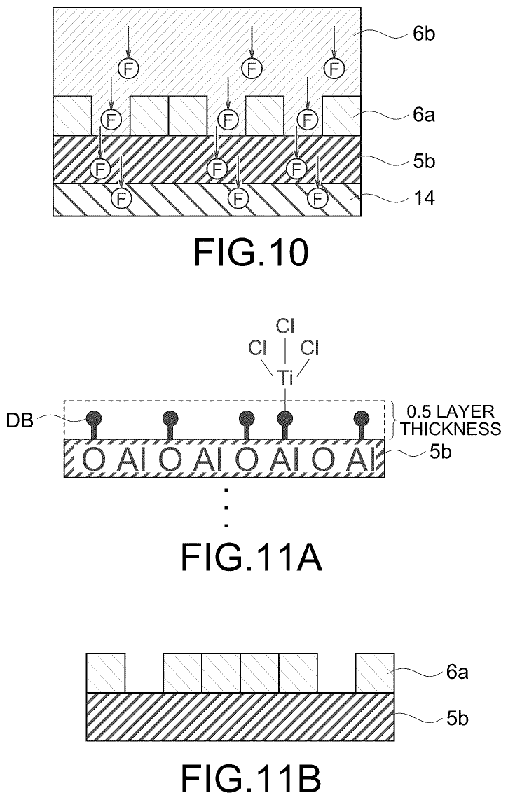

FIG. 10 is a cross sectional view illustrating a method of manufacturing a semiconductor device of a first comparative example of the first embodiment. The first comparative example of the first embodiment is different from the first embodiment in that the film 31 is not provided.

As illustrated in FIG. 10, continuity of the barrier metal layer 6a is poor, and F attributable to the precursor of the electrode material layer 6b diffuses to the insulator 5b and leads to damage on the insulator 5b.

However, in the first embodiment, the film 31 is provided. Accordingly, continuity of the barrier metal layer 6a can be improved. As a result, diffusion of F attributable to the precursor of the electrode material layer 6b can be reduced. Damage on the insulator 5b due to F diffusion can be reduced, and electric property degradation can be reduced.

FIGS. 11A and 11B are cross sectional views illustrating a method of manufacturing a semiconductor device of a second comparative example of the first embodiment. The second comparative example of the first embodiment is different from the first embodiment in that the film 31 is not provided. Note that processes illustrated in FIGS. 11A and 11B are performed after the process illustrated in FIG. 8A.

After the insulator 5b is formed (refer to FIG. 8A), the surface of the insulator 5b is partially removed and initial core adsorption of Ti is performed as illustrated in FIG. 11A. The surface of the insulator 5b is removed by, for example, etching. The insulator 5b at an outermost surface with a thickness of, for example, a 0.5 atomic layer is removed. Ti is adsorbed through dangling bonds DB at the surface of the insulator 5b.

Subsequently, the barrier metal layer 6a is formed as illustrated in FIG. 11B.

In the second comparative example of the first embodiment, continuity of the barrier metal layer 6a, which is equivalent to that in the first embodiment described above with reference to FIG. 8C is obtained. However, in the second comparative example of the first embodiment, the thickness of the insulator 5b is reduced in the process illustrated in FIG. 11A, and thus electric property degradation such as erase saturation degradation potentially occurs.

However, in the first embodiment, since the surface of the insulator 5b is not etched, electric property degradation due to reduction of the thickness of the insulator 5b can be prevented.

### Second Embodiment

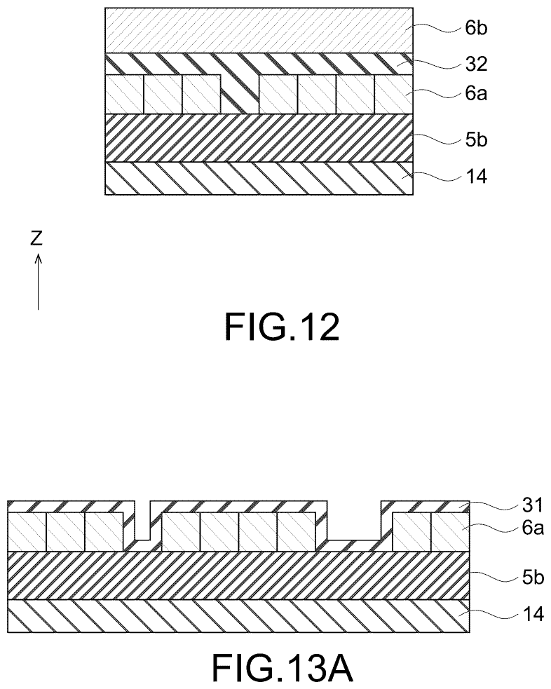

FIG. 12 is a cross sectional view illustrating the structure of a semiconductor device of a second embodiment. FIG. 12 is also an enlarged cross sectional view of the interface between the insulator 5b and the electrode layer 6. In the second embodiment, the position of a film containing C is different from that in the first embodiment.

The semiconductor device further includes a film 32. The film 32 is provided between the barrier metal layer 6a (insulator 5b) and the electrode material layer 6b. The film 32 is, for example, a layer containing boron (B) and carbon. As described later, F that diffuses while the electrode material layer 6b is deposited can be removed by providing the film 32.

Note that, in the example illustrated in FIG. 12, the barrier metal layer 6a is provided between the insulator 5b and the film 32.

Any other component of the semiconductor device according to the second embodiment is the same as the corresponding component of the semiconductor device according to the first embodiment, and thus detailed description thereof is omitted.

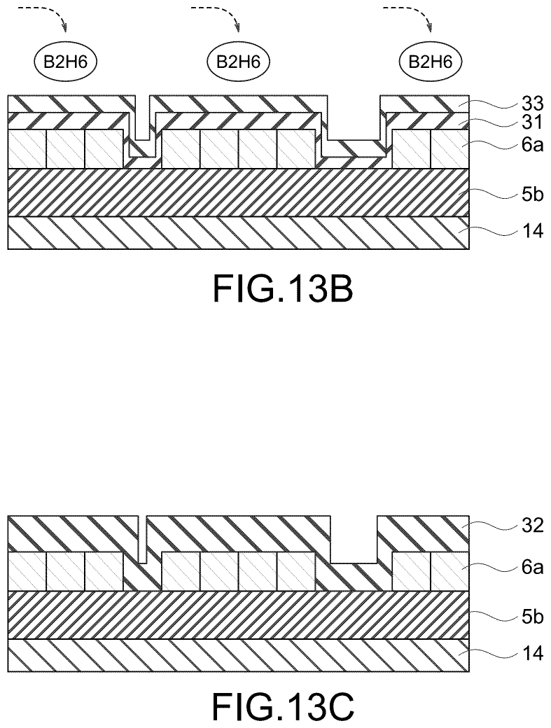

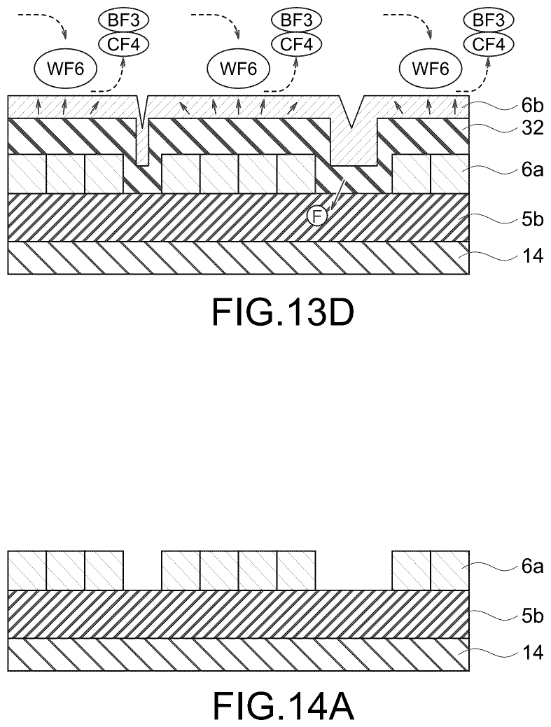

FIGS. 13A to 13D are cross sectional views illustrating a method of manufacturing the semiconductor device of the second embodiment.

First, as illustrated in FIG. 13A, the insulator 5b is formed, the barrier metal layer 6a is formed, and the film 31 is formed.

Subsequently, as illustrated in FIG. 13B, a film 33 is formed on the film 31. The film 33 is a core formation layer of B and formed by supplying B₂H₆. With the film 31, coverage of the film 33 can be improved. This is because B is more likely to adsorb to C than to the barrier metal layer 6a. Moreover, since B is likely to adsorb to C, the adsorption amount of B is larger.

Note that, as illustrated in FIG. 13C, the film 32 is formed as C in the film 31 diffuses to the film 33. The film 31 is thinner than, for example, the film 33. The film 31 and the film 33 are mixed to form the film 32.

Subsequently, as illustrated in FIG. 13D, the electrode material layer 6b is formed on the film 32. The electrode material layer 6b is formed by, for example, LP-CVD. The electrode material layer 6b is formed by supplying WF₆ as the precursor of the electrode material layer 6b. F in WF₆ couples with C in the film 32, and accordingly, CF₄ is generated. F is removed through vaporization of CF₄ during deposition of the electrode material layer 6b. F in WF₆ couples with B in the film 32, and accordingly, BF₃ is generated. F is removed through vaporization of BF₃ during deposition of the electrode material layer 6b. Accordingly, F attributable to the precursor of the electrode material layer 6b can be prevented from diffusing to the insulator 5b.

The film 32 is disposed on the barrier metal layer 6a to react with F. With C contained in the film 32, F becomes easier to remove, and accordingly, F diffusion to the insulator 5b can be further reduced.

Moreover, since the adsorption amount of B is larger, initial adsorption of the electrode material layer 6b is improved. Accordingly, coverage of the electrode material layer 6b is improved. Furthermore, a time in which WF₆ directly contacts the barrier metal layer 6a is shorter, and thus the etching amount of the barrier metal layer 6a can be reduced. In addition, due to the larger adsorption amount of B, a larger amount of B reacts with F that diffuses, and the generation amount of BF₃ becomes larger. Accordingly, F becomes easier to remove.

As in the second embodiment, the position of a film including C may be changed. The semiconductor device according to the second embodiment can obtain the same effects as the semiconductor device according to the first embodiment.

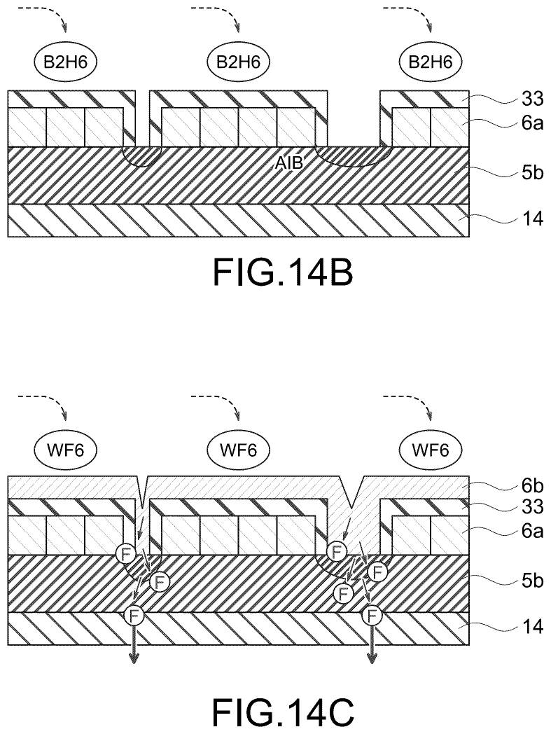

FIGS. 14A to 14C are cross sectional views illustrating a method of manufacturing a semiconductor device of a comparative example of the second embodiment. The comparative example of the second embodiment is different from the second embodiment in that the film 31 (film 32) is not provided.

First, as illustrated in FIG. 14A, the insulator 5b is formed and the barrier metal layer 6a is formed.

Subsequently, as illustrated in FIG. 14B, the film 33 is formed. The film 33 is a core formation layer of B and formed by supplying B₂H₆. Note that Al₂O₃ and B₂H₆ in the insulator 5b react with each other to form AlB (low-k) at a part where the barrier metal layer 6a is discontinuous, in other words, at a part where the insulator 5b is exposed.

Subsequently, as illustrated in FIG. 14C, the electrode material layer 6b is formed. The electrode material layer 6b is formed by, for example, LP-CVD. The electrode material layer 6b is formed by supplying WF₆ as the precursor of the electrode material layer 6b. For example, at a part where the barrier metal layer 6a is discontinuous, F attributable to the precursor of the electrode material layer 6b diffuses to the insulator 5b and the insulating layer 14.

However, in the second embodiment, since B is likely to adsorb to C and the film 31 is provided, the film 33 is likely to be formed at a part where the barrier metal layer 6a is discontinuous. Accordingly, diffusion of F attributable to the precursor of the electrode material layer 6b can be reduced at a part where the barrier metal layer 6a is discontinuous.

### Third Embodiment

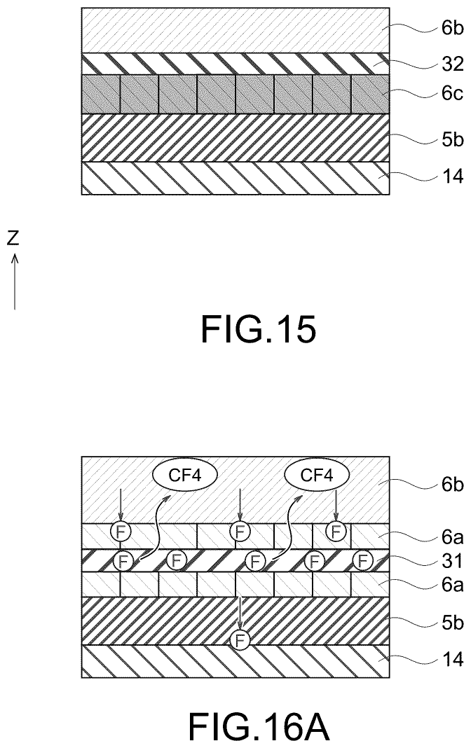

FIG. 15 is a cross sectional view illustrating the structure of a semiconductor device of a third embodiment. FIG. 15 is an enlarged cross sectional view of the interface between the insulator 5b and the electrode layer 6. The third embodiment is different from the second embodiment in that the barrier metal layer contains C.

The semiconductor device includes a barrier metal layer 6c in place of the barrier metal layer 6a. The barrier metal layer 6c contains C. Specifically, the barrier metal layer 6c of the third embodiment contains C at higher concentration than the barrier metal layer 6a of the second embodiment. The barrier metal layer 6c contains, for example, TiCN.

Any other configuration of the semiconductor device according to the third embodiment is the same as the corresponding component of the semiconductor device according to the third embodiment, and thus detailed description thereof is omitted.

FIGS. 16A and 16B are cross sectional views illustrating a method of manufacturing the semiconductor device of the third embodiment.

First, as illustrated in FIG. 16A, the insulator 5b is formed, the barrier metal layers 6a and the film 31 are alternately formed, and then, the electrode material layer 6b is formed. In the example illustrated in FIG. 16A, the film 31 is formed between the two barrier metal layers 6a.

Note that, as illustrated in FIG. 16B, the barrier metal layer 6c is formed as C in the film 31 diffuses to the barrier metal layers 6a. At formation of the electrode material layer 6b, B₂H₆ is supplied to the outermost surface of the barrier metal layer 6c. As C in the barrier metal layer 6c and B₂H₆ react with each other, the extremely thin film 32 containing B and C is formed between the barrier metal layer 6c and the electrode material layer 6b.

The electrode material layer 6b is formed by supplying WF₆ as the precursor of the electrode material layer 6b. F in WF₆ couples with C in the film 32 and the barrier metal layer 6c, and accordingly, CF₄ is generated. F is removed through vaporization of CF₄ during deposition of the electrode material layer 6b. F in WF₆ couples with B in the film 32, and accordingly, BF₃ is generated. F is removed through vaporization of BF₃ during deposition of the electrode material layer 6b. Accordingly, F attributable to the precursor of the electrode material layer 6b can be prevented from diffusing to the insulator 5b.

The film 32 and the barrier metal layer 6c are disposed to react with F. With C contained in the film 32 (film 31) and the barrier metal layer 6c, F becomes easier to remove, and accordingly, F diffusion to the insulator 5b can be further reduced.

Note that the barrier metal layer 6c may be directly formed in place of the alternate formation of the barrier metal layers 6a and the film 31.

The barrier metal layer 6c may contain S1 in place of C in a case where the film 32 contains S1 in place of C.

As in the third embodiment, the barrier metal layer may contain C. The semiconductor device according to the third embodiment can obtain the same effects as the semiconductor device according to the second embodiment.

### Fourth Embodiment

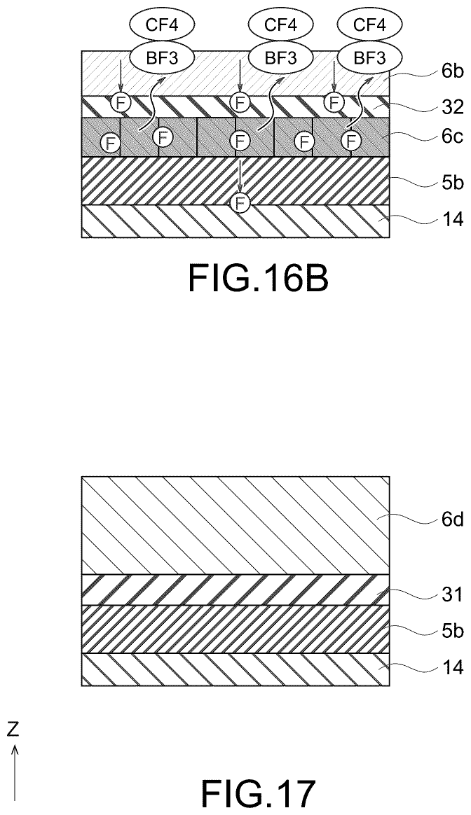

FIG. 17 is a cross sectional view illustrating the structure of a semiconductor device of a fourth embodiment. FIG. 17 is an enlarged cross sectional view of the interface between the insulator 5b and the electrode layer 6. The fourth embodiment is different from the first embodiment in that the material of the electrode material layer is different.

The semiconductor device includes an electrode material layer 6d in place of the electrode material layer 6b. The electrode material layer 6d is, for example, a molybdenum (Mo) layer.

In the fourth embodiment, the barrier metal layer 6a is not provided. This is because diffusion of F attributable to the precursor of the electrode material layer 6b does not need to be prevented since the electrode material layer 6b is not formed.

The film 31 is provided between the insulator 5b and the electrode material layer 6d. The film 31 is, for example, a layer containing carbon (C). As described later, when the film 31 is provided, O* that diffuses can be trapped by the film 31, and accordingly, electric property degradation due to O* diffusion to the insulator 5b and the insulating layer 14 can be reduced.

Any other configuration of the semiconductor device according to the fourth embodiment is the same as the corresponding component of the semiconductor device according to the first embodiment, and thus detailed description thereof is omitted.

FIG. 18 is a cross sectional view illustrating a method of manufacturing the semiconductor device of the fourth embodiment.

First, the insulator 5b is formed, the film 31 is formed, and the electrode material layer 6d is formed. For example, NH₃ is used as material gas of a core formation layer of the electrode material layer 6d. O* diffuses from the electrode material layer 6d to the insulator 5b. The film 31 traps O* that diffuses before the insulator 5b. Accordingly, electric property degradation due to O* diffusion to the insulator 5b can be reduced.

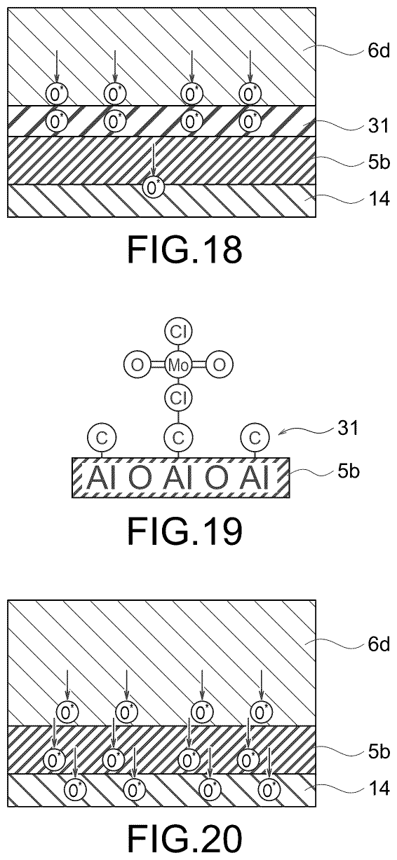

FIG. 19 is a cross sectional view illustrating the method of manufacturing the semiconductor device of the fourth embodiment.

The electrode material layer 6d is formed by supplying MoO₂C1₂ as the precursor of the electrode material layer 6d. With the film 31, the precursor of the electrode material layer 6d is more likely to adsorb through C-C1, and accordingly, the adsorption amount of the precursor can be increased.

FIG. 20 is a cross sectional view illustrating the structure of a semiconductor device of a comparative example of the fourth embodiment. The comparative example of the fourth embodiment is different from the fourth embodiment in that the film 31 is not provided.

As illustrated in FIG. 20, since the film 31 is not provided, O* potentially diffuses to the insulator 5b and the insulating layer 14. If O* diffuses to the insulator 5b and the insulating layer 14, electric properties are affected, which potentially leads to device performance degradation.

However, in the fourth embodiment, with the film 31, O* that diffuses can be trapped by the film 31, and accordingly, electric property degradation due to O* diffusion to the insulator 5b can be reduced.

As in the fourth embodiment, the material of the electrode material layer may be changed. The semiconductor device according to the fourth embodiment can obtain the same effects as the semiconductor device according to the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first insulator;
a conductive layer; and
a film provided between the first insulator and the conductive layer and containing carbon (C) or silicon (Si).

2. The semiconductor device according to claim 1, further comprising a first barrier metal film provided between the film and the conductive layer.

3. The semiconductor device according to claim 2, wherein the conductive layer contains tungsten (W).

4. The semiconductor device according to claim 1, further comprising a second barrier metal film provided between the first insulator and the film.

5. The semiconductor device according to claim 4, wherein the second barrier metal film contains carbon or silicon.

6. The semiconductor device according to claim 4, wherein
the conductive layer contains tungsten, and
the film further contains boron (B).

7. The semiconductor device according to claim 1, wherein the conductive layer contains molybdenum (Mo).

8. The semiconductor device according to claim 2, wherein the concentration of carbon between the first insulator and the conductive layer is equal to or higher than a predetermined value.

9. The semiconductor device according to claim 8, wherein the predetermined value is 1×10¹⁹ atom/cm³.

10. The semiconductor device according to claim 1, further comprising:
a stacked body in which insulating layers and the conductive layers are alternately stacked in a first direction;
a semiconductor layer disposed in the first direction in the stacked body;
a second insulator disposed in the first direction between the stacked body and the semiconductor layer;
a third insulator disposed in the first direction between the stacked body and the second insulator; and
a fourth insulator disposed in the first direction between the stacked body and the third insulator, wherein
the first insulator is disposed between the conductive layers and the insulating layers and between the conductive layers and the fourth insulator.

11. The semiconductor device according to claim 10, further comprising a first barrier metal film provided between the film and the conductive layer.

12. The semiconductor device according to claim 11, wherein the conductive layer contains tungsten (W).

13. The semiconductor device according to claim 10, further comprising a second barrier metal film provided between the first insulator and the film.

14. The semiconductor device according to claim 13, wherein the second barrier metal film contains carbon or silicon.

15. The semiconductor device according to claim 13, wherein
the conductive layer contains tungsten, and
the film further contains boron (B).

16. The semiconductor device according to claim 10, wherein the conductive layer contains molybdenum (Mo).

17. The semiconductor device according to claim 11, wherein the concentration of carbon between the first insulator and the conductive layer is equal to or higher than a predetermined value.

18. The semiconductor device according to claim 1, further comprising a wire disposed at the first insulator and including the conductive layer.

19. The semiconductor device according to claim 5, wherein
the conductive layer contains tungsten, and
the film further contains boron (B).

20. A semiconductor device manufacturing method comprising:
forming a first insulator;
forming a film containing carbon (C) or silicon (Si) above the first insulator; and
forming a conductive layer above the film.
